(19) United States
(12) Patent Application Publication
(10) Pub. No.: US 2026/0172680 A1
(43) Pub. Date: Jun. 18, 2026

(54) ACTUATOR FOR CAMERA AND SUPPORTING MEMBER EQUIPPED THEREIN

(71) Applicant: JAHWA electronics Co., Ltd., Chungcheongbuk-do (KR)

(72) Inventors: SANG HWA LEE, Chungcheongbuk-do (KR); JONG HAN KIM, Chungcheongbuk-do (KR)

(21) Appl. No.: 19/328,569

(22) Filed: Sep. 15, 2025

(30) Foreign Application Priority Data
Dec. 13, 2024 (KR) 10-2024-0186189

(51) Int. Cl. H04N 23/68; H04N 23/54

(52) U.S. Cl. CPC H04N 23/687; H04N 23/54

(57) ABSTRACT

An actuator for a camera according to an embodiment of the present disclosure includes a first carrier configured to move in at least one direction, a housing configured to support the movement of the first carrier, a second carrier configured to move in at least one direction relative to the first carrier and having a magnet installed thereon, a coil configured to face the magnet, a circuit board including a first part fixed to the housing, a second part fixed to the first carrier and configured such that the coil is installed thereon, and a connection part that connects the first and second parts and has at least one bending region, and a supporting member provided in the bending region and configured to physically support the bending region.

### CROSS-REFERENCE TO RELATED APPLICATION AND CLAIM OF PRIORITY

This application claims the benefit under 35 USC §119 of Korean Patent Application No. 10-2024-0186189, filed on December 13, 2024, in the Korean Intellectual Property Office, the entire disclosure of which is incorporated herein by reference for all purposes.

### BACKGROUND

### TECHNICAL FIELD

The present disclosure relates to an actuator for a camera, and more specifically, to an actuator for a camera, which includes a supporting member that physically supports a bending region of a circuit board connecting a moving body and a fixed body.

### BACKGROUND ART

Advances in hardware technology for image processing and growing consumer need for making and taking photos and videos have driven implementation of such functions as autofocusing (AF) and optical image stabilization (OIS) in stand-alone cameras as well as camera modules mounted on mobile terminals including cellular phones and smartphones.

An autofocus (AF) function (or, an automatically focusing function) means a function of a focal length to a subject by linearly moving a carrier having a lens in an optical axis direction to generate a clear image at an image sensor (CMOS, CCD, etc.) located at the rear of the lens.

An optical image stabilization (OIS) function means a function of improving the sharpness of an image by adaptively moving the carrier having a lens in a direction to compensate for the shaking when the lens is shaken due to trembling.

One typical method for implementing the AF or OIS function is to install a magnet (a coil) on a mover (a carrier) and install a coil (a magnet) on a stator (a housing, or another type of carrier, or the like), and then generate an electromagnetic force between the coil and the magnet so that the mover moves in the optical axis direction or in a direction perpendicular to the optical axis.

In the case of a device or actuator that integrates AF and OIS functions, the AF requires movement in the optical axis direction and the OIS requires movement in a direction perpendicular to the optical axis, so it is implemented as a complex physical structure in which the AF and OIS carriers are mutually stacked.

The coil that generates a driving force to move the moving body is mounted on a circuit board on which power supply lines or patterns are formed. It is desirable that the circuit board is connected to the outermost part of the actuator for interfacing with power supply, control signals, etc.

Therefore, in the case of an actuator that integrates AF and OIS, i.e. an actuator in which multiple moving bodies move relative to each other, a circuit board that physically connects a moving body located inside and a fixed body (e.g., a housing, a case, a base, etc.) relative to the moving body is generally included.

The circuit board mainly employs a flexible printed circuit board (FPCB) that has elasticity to allow free movement, and the circuit board (FPCB) has at least one bending region with an appropriate angle or radius to ensure space efficiency and eliminate interference with other components.

The bending region (or, the circuit board including the bending region) is made of an elastic material and thus has the physical property to resolve the folded or bent state, i.e., to be straightened out. Therefore, over time, the originally intended bending shape of the bending region may be not maintained, such as protruding outward, and this may result in interference between the bending region and/or other parts of the circuit board and other components, damage to the circuit board due to external impact, or disconnection of wiring lines formed on the circuit board.

In particular, in the case of an actuator for a camera, since the OIS carrier and/or the AF carrier moves at a very fast speed and the frequency of movement is also very high, the above phenomenon may occur more easily, and this phenomenon may directly lead to problems such as inability to drive, reduced driving precision, or AF/OIS driving errors.

### SUMMARY

The present disclosure is designed to solve the problems of the related art, and therefore the present disclosure is directed to providing an optical (for a camera) actuator, which may constantly maintain driving precision even during continuous and long-term use through structural improvements that physically support and protect a bending region of a circuit board connected to both a moving body and a fixed body.

Other technical goals and advantages of the present invention can be understood with reference to the description below, which will be made explicit by the accompanied examples. Furthermore, the technical goals and advantages of the present invention can be accomplished by the embodiments and their combinations recited in the attached claims.

An actuator for a camera according to an embodiment of the present disclosure to accomplish the above object includes an actuator for a camera, including: a first carrier configured to move in at least one direction; a housing configured to support the movement of the first carrier; a second carrier configured to move in at least one direction relative to the first carrier and having a magnet installed thereon; a coil configured to face the magnet; a circuit board including a first part fixed to the housing, a second part fixed to the first carrier and configured such that the coil is installed thereon, and a connection part that connects the first and second parts and has at least one bending region; and a supporting member provided in the bending region and configured to physically support the bending region.

Here, the supporting member of the present disclosure preferably has a bending shape.

Specifically, the supporting member of the present disclosure may include a body portion coupled to the bending region; and a hole configured to expose a center portion of the bending region, and in this case, the hole preferably has a bending shape.

Depending on an embodiment, the hole of the present disclosure may have a shape of an elongated hole that extends in a longitudinal direction of the bending region, and the hole is preferably configured to have a greater height than the bending region.

Preferably, the supporting member of the present disclosure further include a slit that connects a lower or upper portion of the body portion and the hole and is configured such that the bending region is fitted therein.

In addition, the bending region of the present disclosure preferably has a smaller height or thickness than other portions of the connection part.

A supporting member according to an embodiment of the present disclosure includes a first part fixed to a fixed body, a second part fixed to a moving body and configured such that a coil is mounted thereon, and a connection part connecting the first and second parts and having at least one bending region, and includes a body portion coupled to the bending region; and a hole configured to expose a center portion of the bending region, and the supporting member is configured to physically support the bending region.

In a preferred embodiment of the present disclosure, since the bending region of a circuit board (flexible circuit board) connected to both a moving body and a fixed body is effectively supported, the original shape and structure of the bending region may be continuously maintained.

In a preferred embodiment of the present disclosure, since the supporting member supporting the bending region is divided into a part that is directly coupled to the bending region and a part that is not coupled to the bending region but exposes a part of the bending region, the weight of the supporting member itself may be reduced and excessive restraining force may not be applied to the bending region, thereby protecting the bending region more effectively.

According to a preferred embodiment of the present disclosure, since a slit structure that is coupled with the bending region in the upper or lower direction is formed on the supporting member, the process of coupling with the bending region, etc. may be implemented more effectively.

### BRIEF DESCRIPTION OF THE DRAWINGS

The accompanying drawings illustrate a preferred embodiment of the present disclosure and together with the foregoing disclosure, serve to provide further understanding of the technical features of the present disclosure, and thus, the present disclosure is not construed as being limited to the drawing.

FIG. 1 is a drawing showing the overall configuration of an actuator for a camera according to a preferred embodiment of the present disclosure,

FIGS. 2 to 4 are drawings showing the detailed configuration of the actuator for a camera,

FIG. 5 is a drawing showing an embodiment of a circuit board and a supporting member installed on the circuit board,

FIG. 6 is a drawing showing the detailed configuration of the supporting member,

FIG. 7 is a drawing showing another embodiment of the supporting member, and

FIG. 8 is a drawing showing an embodiment of a connection part of the circuit board.

### DETAILED DESCRIPTION

Hereinafter, preferred embodiments of the present disclosure will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation.

Therefore, the description proposed herein is just a preferable example for the purpose of illustrations only, not intended to limit the scope of the disclosure, so it should be understood that other equivalents and modifications could be made thereto without departing from the scope of the disclosure.

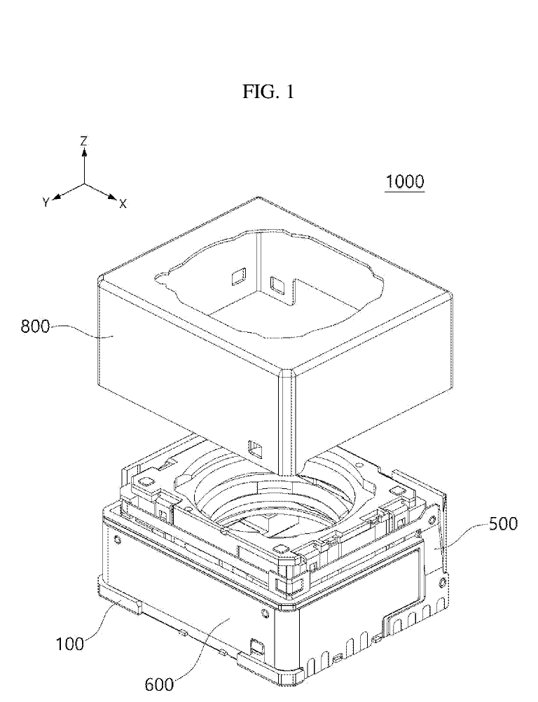

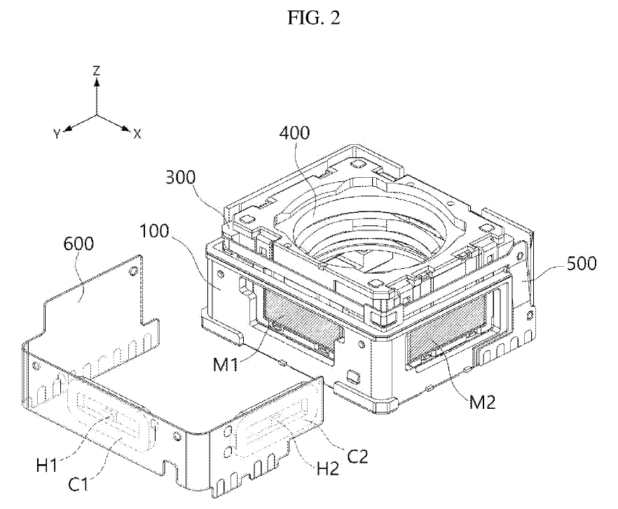

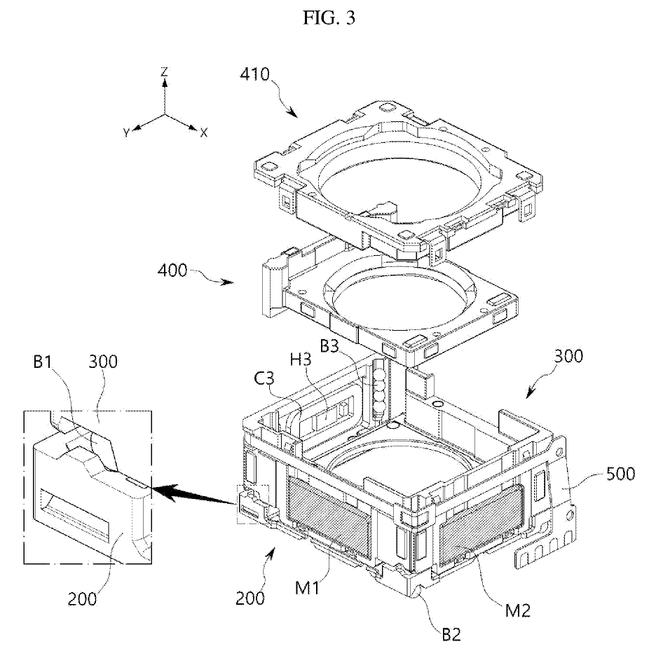

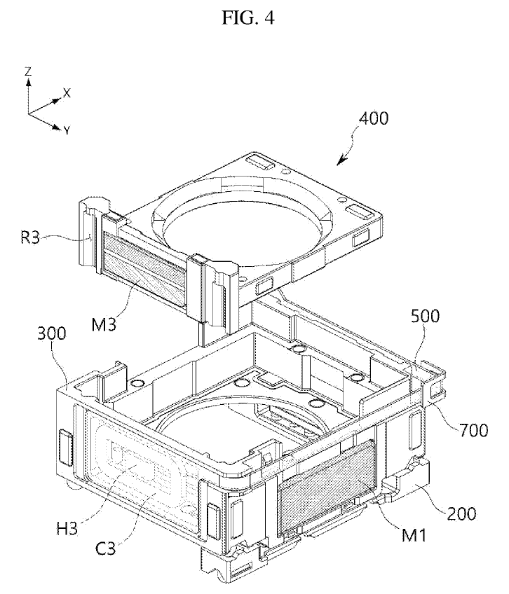

FIGS. 1 to 4 are drawings showing the configuration of an actuator 1000 for a camera (hereinafter referred to as “actuator”) according to a preferred embodiment of the present disclosure.

Hereinafter, the overall configuration of the present disclosure and the operational relationship of AF and OIS will first be explained with reference to the drawings, and a supporting member 700 of the present disclosure that supports a bending region 510C of a circuit board 500 will be described in detail later.

As shown in FIG. 1 or the like, the actuator 1000 according to an embodiment of the present disclosure may be configured to include a housing 100, a middle guide 200, a first carrier 300, a second carrier 400, and a case 800.

The Z-axis direction shown in FIG. 1 is an optical axis direction in which light enters a lens or a lens assembly (not shown), and corresponds to a direction in which the second carrier 400 moves forward and backward when AF is driven. Also, the X-axis and Y-axis, which are perpendicular to the optical axis, correspond to directions in which the first carrier 300 moves when OIS is driven.

Hereinafter, in describing the embodiment of the present disclosure, one of two directions perpendicular to the optical axis is referred to as a first direction (Y-axis direction) and the other as a second direction (X-axis direction). However, this is only an example according to a relative viewpoint, and it is also possible that either the X-axis direction or the Y-axis direction is the first direction and the other direction is the second direction.

It is obvious that the axes depicted in the drawings, terms referring to the axes, and terms such as upper, lower, front, rear, vertical, horizontal, etc., which are explained based on the axes, are only intended to present relative standards for explaining embodiments of the present disclosure, and are not intended to specify any direction or position on an absolute basis, and may of course vary relatively depending on the position of a target object, the position or direction of view, etc.

The housing 100 of the present disclosure corresponds to a basic frame structure that accommodates internal components of the actuator 1000 according to the present disclosure, and may be coupled with a case 800 that functions as a shield can depending on an embodiment.

The first carrier 300 is a moving body that moves in the first direction and/or the second direction with the housing 100 as a relative fixed body. OIS is implemented by moving a lens or image sensor due to the movement of the first carrier 300, thereby eliminating external disturbances such as hand tremor.

In this respect, the first carrier 300 corresponds to a moving body moving relative to the housing 100, and from a corresponding point of view, the housing 100 corresponds to a relatively fixed body.

Depending on an embodiment, the actuator 1000 of the present disclosure may further include a middle guide 200 disposed between the first carrier 300 and the housing 100.

In this embodiment, a first ball B1 may be disposed between the first carrier 300 and the middle guide 200, and a second ball B2 may be disposed between the middle guide 200 and the housing 100.

For effective implementation of linear guiding, it is preferable that the first ball B1 be provided to be partially accommodated in a rail formed on at least one of the first carrier 300 and the middle guide 200. From a corresponding perspective, the second ball B2 may be provided to be partially accommodated in a rail formed on at least one of the middle guide 200 and the housing 100.

If the first ball B1 is provided in this way, the first carrier 300 maintains an appropriate interval with the middle guide 200, and may linearly move more flexibly with minimized friction due to moving and rolling of the first ball B1, thereby further improving noise reduction, minimization of driving force, driving precision, etc. The same also applies to the second ball B2.

A first magnet M1 and a second magnet M2 that face the first coil C1 and the second coil C2, respectively, may be installed on the first carrier 300. Depending on an embodiment, the first magnet M1 and the second magnet M2 may be provided on the second carrier 300 and the middle guide 200, and are provided in directions orthogonal to each other.

The first and second magnets M1 and M2 correspond to the OIS magnets for OIS driving, and the first and second coils C1 and C2 correspond to the coils for OIS driving.

If power of appropriate magnitude and direction is supplied to the first coil C1, a magnetic force (electromagnetic force) is generated between the first magnet M1 installed on the first carrier 300 and the first coil C1, and the first carrier 300 moves in the first direction (Y-axis direction) with respect to the middle guide 200 using the generated magnetic force as a driving force.

Depending on an embodiment, a detection sensor such as the first hall sensor H1 may be further included. In this case, if the first hall sensor H1 detects the position of the first magnet M1 installed on the first carrier 300 using the Hall effect or the like and transmits a corresponding signal to the operation drive, the operation drive controls power of a corresponding magnitude and direction to be cyclically supplied to the first coil C1.

The operation drive may be implemented as an independent electronic component, element, etc., but may also be implemented as a single electronic component (chip) integrated with the first hall sensor H1 through SOC (System On Chip) or the like.

From a corresponding viewpoint, if power of appropriate magnitude and direction is supplied to the second coil C2, a magnetic force (electromagnetic force) is generated between the second magnet M2 of the first carrier 300 and the second coil C2, and the first carrier 300 moves in the second direction (X-axis direction) relative to the housing 100 with the generated magnetic force as a driving force.

Specifically, the rail formed at the point where the first carrier 300 and the middle guide 200 face each other and the rail formed at the point where the middle guide 200 and the housing 100 face each other are arranged to be orthogonal to each other. Since the first ball B1 and the second ball B2 are arranged on each of these rails, when a driving force in the second direction is generated, the first carrier 300 moves in the second direction together with the middle guide 200 with the housing 100 as a relatively fixed body. The features of the second hall sensor H2 corresponds to the features of the first hall sensor H1 described above, and will not described again.

It is preferable that the first circuit board 600, on which the first coil C1, the first hall sensor H1, the second coil C2, and the second hall sensor H2 are mounted, is provided in the housing 100 located at the outermost side of the actuator 1000 for interfacing with external devices, etc.

The second carrier 400 corresponds to a moving body that implements AF by moving in the optical axis direction (Z-axis direction) with the first carrier 300 described above as a relative fixed body. Depending on an embodiment, a carrier cover 410 may be included to prevent the second carrier 400 from being deviated to the outside.

In order to guide the movement of the second carrier 400 in the optical axis direction, a third rail R3 having a shape extending in the optical axis direction and on which a third ball B3 is arranged may be formed on at least one of the second carrier 400 and the first carrier 300.

A third magnet M3 that faces the third coil C3 installed on the first carrier 300 is installed on the second carrier 400. If power of an appropriate magnitude and direction is supplied to the third coil C3 through position detection of the third hall sensor H3 and control of the operation drive, an electromagnetic force (magnetic force) is generated between the third coil C3 and the third magnet M3, and the second carrier 400 moves in the optical axis direction using this electromagnetic force as a driving force.

If the second carrier 400 moves forward and backward in the optical axis direction in this way, the distance between the lens and an image sensor (not shown), such as a CCD (Charged-coupled Device) or CMOS (Complementary Metal-oxide Semiconductor) installed at the rear end of the actuator 1000 (based on the optical axis direction), is adjusted, thereby implementing an auto-focus function or a zoom function.

In this respect, the first carrier 300 functions as a relative moving body for the OIS operation described above, but functions as a relative fixed body for the second carrier 400 for the AF operation.

Since the third coil C3, which generates an electromagnetic force to the third magnet M3 (installed on the second carrier 400), is installed on the first carrier 300, which functions as a moving body in OIS operation, if the first carrier 300 moves by OIS operation (in the combined direction of the first and second directions), the third coil C3 moves together with the first carrier 300.

Therefore, it is desirable that the circuit board 500 interfacing the external device and the third coil C3 is implemented as a flexible circuit board (FPCB) that has flexibility and elasticity so that the above movement of the first carrier 300 may be adaptively reflected.

The circuit board 500 is connected to both the fixed body and the moving body in this way. Since the supporting member 700 of the present disclosure is provided in the circuit board 500, the supporting member 700 of the present disclosure may be applied not only to the actuator 1000 of the embodiment depicted in the drawings, but also to an actuator that moves or rotates a reflector, which is an actuator in which a relative moving body is compositely configured.

Hereinafter, the circuit board 500 and the supporting member 700 installed on the circuit board 500 will be described in detail.

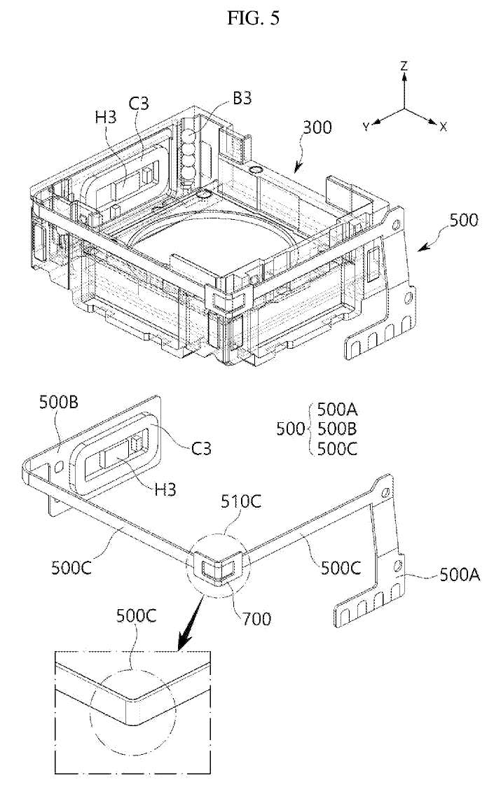

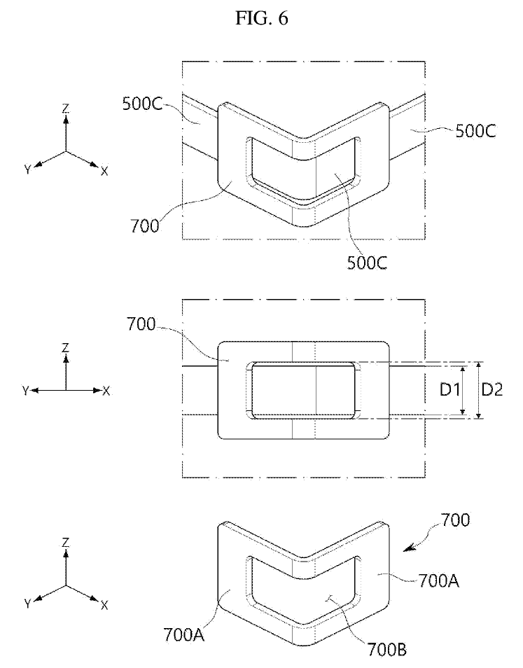

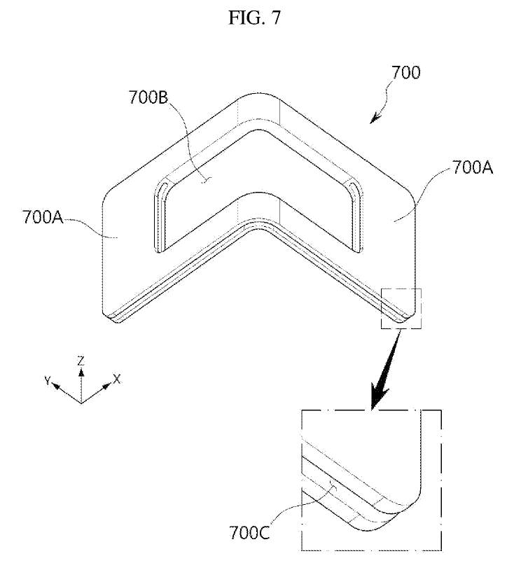

FIG. 5 is a drawing showing an embodiment of a circuit board 500 and a supporting member 700 installed on the circuit board 500, FIG. 6 is a drawing showing the detailed configuration of the supporting member 700, and FIG. 7 is a drawing showing another embodiment of the supporting member 700.

As illustrated in FIG. 5, the circuit board 500 may specifically include a first part 500A fixed to the housing 100, a second part 500B fixed to the first carrier 300 and configured such that the third coil C3 is installed thereon, and a connection part 500C connecting the first part 500A and the second part 500B.

Even though the drawings show that the first circuit board 600, on which the first coil C1 or the like is mounted, and the circuit board 500, on which the third coil C3 or the like is mounted, are in a dualized form, depending on an embodiment, the first part 500A of the circuit board 500 fixed to the housing 100 may be implemented in a unified form with the first circuit board 600.

Since the first part 500A and the second part 500B cannot be provided on the same surface due to the arrangement of the magnetic configuration (coil, magnet) for direction control, the connection part 500C connecting the first part 500A and the second part 500B has a shape that extends along a path corresponding to the outer shape of the first carrier 300 or the like, and includes at least one bending region 510C.

Even though the drawings show the bending region 510C having a right-angled bent shape, depending on the shape of the first carrier 300, etc., or an adaptive structure to avoid interference with other adjacent components, the bending region 510C may be bent at various angles or have a folded shape or a rounded shape.

Since the flexible circuit board is made of elastic material, even if it is bent to a designed angle, the flexible circuit board has the property of straightening out over time due to its own restoring force without maintaining the designed bending angle or shape.

Since the connection part 500C of the circuit board 500 made of FPCB moves repeatedly at high speed, the restoring force of the bending region 510C may be more easily implemented, and as a result, the shape deformation of the bending region 510C may occur more easily.

The supporting member 700 of the present disclosure physically supports and protects the bending region 510C so that the bending region 510C continuously maintains its original shape or structure.

In order to suppress the shape deformation of the bending region 510C due to its own elasticity, etc., it is preferable that the supporting member 700 is made of a material having higher physical rigidity than the bending region 510C.

Since the supporting member 700 of the present disclosure is a configuration that is coupled to the circuit board 500, it is desirable that the supporting member 700 is made of non-magnetic material such as polymer materials, plastic, SUS, etc., so as to minimize the impact on the lines or patterns of the circuit board 500.

As shown in the drawings, it is preferable that the supporting member 700 of the present disclosure has a bending shape corresponding to the bending region 510C of the circuit board 500.

In addition, it is preferable that the overall height (Z-axis direction) of the supporting member 700 is configured to be higher than the overall height of the bending region 510C so as to prevent the bending region 510C from directly colliding with other components located in the upper and lower direction (Z-axis direction) due to high-speed movement or vibration, etc., as well as prevent the bending region 510C from being damaged by collision, impact, etc.

Specifically, the supporting member 700 according to one embodiment of the present disclosure may include a body portion 700A that is directly connected to the bending region 510C, and a hole 700B that is formed in a central portion of the supporting member 700 and exposes a central portion of the bending region 510C.

Through this configuration, since the center portion of the bending region 510C is exposed through the hole 700B of the supporting member 700, the bending region 510C may be induced to flow or move within a limited range.

According to the embodiment of the present disclosure, since the physical support force by the supporting member 700 and the elastic force of the bending region 510C itself may be induced to be organically and harmoniously expressed, damage or stress applied to the bending region 510C due to the rigidity of the supporting member 700 itself may be effectively alleviated.

In order to more effectively implement this function of the supporting member 700, it is preferable that the hole 700B formed in the supporting member 700 has a bending shape corresponding to the bending region 510C, particularly the center portion of the bending region 510C, and as illustrated in the drawings, it is preferable that the supporting member 700 has a bending shape, but is formed in the shape of an elongated hole extending in the longitudinal direction of the bending region 510C.

It is preferable that the height D2 of the hole 700B formed in the supporting member 700 is configured to be higher than the height D1 of the bending region 510C so that the bending region 510C, specifically the bending region 510C exposed to the outside through the hole 700B of the supporting member 700, may effectively flow or move.

As illustrated in FIG. 7, the supporting member 700 of the present disclosure may include a slit 700C that spatially connects the lower portion of the body portion 700A and the hole 700B and is configured such that the bending region 510C is fitted therein.

If the slit 700C is formed on the supporting member 700 in this way, the supporting member 700 may be easily fitted and coupled from the upper portion to the lower portion of the bending region 510C, so that the coupling process may be implemented more simply, and the supporting member 700 may be coupled to the bending region 510C more accurately. In addition, when adhesive is applied to couple the supporting member 700 and the bending region 510C, the adhesive may be introduced through the slit, so that the bonding process may also be implemented more effectively.

Even though the drawing shows an embodiment in which the slit 700C is provided at the lower portion of the supporting member 700, depending on an embodiment, the slit 700C may be provided at the upper portion of the supporting member 700. If the slit 700C is provided at the upper portion of the supporting member 700, the supporting member 700 may be fitted in the upper direction from the lower portion of the bending region 510C.

The supporting member 700 of the present disclosure may be coupled with the bending region 510C by means of adhesive or bonding, and may also have a fitting or catch portion, such as a clip, depending on an embodiment, so that the supporting member 700 may be coupled with the bending region 510C through such means, or may be coupled with the bending region 510C in the form of elastically supported tongs, etc.

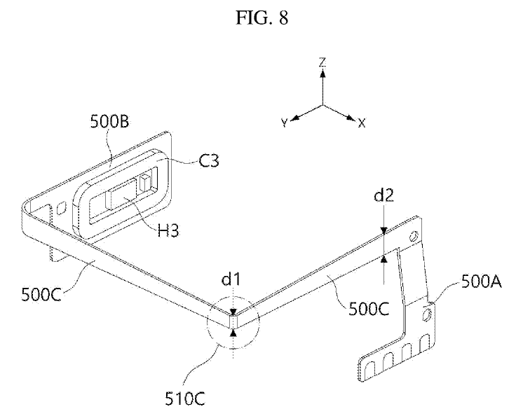

FIG. 8 is a drawing showing an embodiment of a connection part 500C of the circuit board 500.

As illustrated in the drawing, it is preferable that the height (d1) of the bending region 510C is configured to be smaller than the height (d2) of other portions of the connection part 500C.

In this configuration, the physical rigidity of the connection part 500C, which is close to the first part 500A or/and the second part 500B of the circuit board 500, which is a fixed part, may be induced to be greater than that of the bending region 510C, thereby suppressing the phenomenon that the bending region 510C sags in the downward direction due to a load, etc., and also reducing the physical property of the bending region 510C to be straightened due to elastic restoring force.

In order to further enhance this effect, as illustrated in the drawing, it is preferable that the connection part 500C is configured to have a height that gradually decreases from the first part 500A or/and the second part 500B to the bending region 510C.

From a corresponding viewpoint, it is desirable that the thickness (X-axis or Y-axis based on the drawing) of the bending region 510C is configured to be smaller than that of other portions of the connection part 500C.

The present disclosure has been described in detail. However, it should be understood that the detailed description and specific examples, while indicating preferred embodiments of the disclosure, are given by way of illustration only, since various changes and modifications within the scope of the disclosure will become apparent to those skilled in the art from this detailed description.

In the above description of this specification, the terms such as “first” and “second” etc. are merely conceptual terms used to relatively identify components from each other, and thus they should not be interpreted as terms used to denote a particular order, priority or the like.

The drawings for illustrating the present disclosure and its embodiments may be shown in somewhat exaggerated form in order to emphasize or highlight the technical contents of the present disclosure, but it should be understood that various modifications may be made by those skilled in the art in consideration of the above description and the illustrations of the drawings without departing from the scope of the present invention.

What is claimed is:

1. An actuator for a camera, comprising:
a first carrier configured to move in at least one direction;
a housing configured to support the movement of the first carrier;
a second carrier configured to move in at least one direction relative to the first carrier and having a magnet installed thereon;
a coil configured to face the magnet;
a circuit board including a first part fixed to the housing, a second part fixed to the first carrier and configured such that the coil is installed thereon, and a connection part that connects the first and second parts and has at least one bending region; and
a supporting member provided in the bending region and configured to physically support the bending region.

2. The actuator for a camera according to claim 1, wherein the supporting member has a bending shape.

3. The actuator for a camera according to claim 2, wherein the supporting member includes:
a body portion coupled to the bending region; and
a hole configured to expose a center portion of the bending region.

4. The actuator for a camera according to claim 3, wherein the hole has a bending shape.

5. The actuator for a camera according to claim 3, wherein the hole has a shape of an elongated hole that extends in a longitudinal direction of the bending region.

6. The actuator for a camera according to claim 3, wherein the hole has a greater height than the bending region.

7. The actuator for a camera according to claim 3, wherein the supporting member further includes a slit that connects a lower or upper portion of the body portion and the hole and is configured such that the bending region is fitted therein.

8. The actuator for a camera according to claim 1, wherein the bending region has a smaller height or thickness than other portions of the connection part.

9. A supporting member provided to a circuit board including a first part fixed to a fixed body, a second part fixed to a moving body and configured such that a coil is mounted thereon, and a connection part connecting the first and second parts and having at least one bending region, the supporting member comprising:
a body portion coupled to the bending region; and
a hole configured to expose a center portion of the bending region,
wherein the supporting member physically supports the bending region.
